(19) United States
(12) Patent Application Publication
(10) Pub. No.: US 2024/0128292 A1
(43) Pub. Date: Apr. 18, 2024

(54) OPTOELECTRONIC MODULE

(71) Applicant: ams-OSRAM Asia Pacific Pte. Ltd., Singapore (SG)

(72) Inventors: Harald ETSCHMAIER, Graz (AT); Gerhard PEHARZ, Gleisdorf (AT); Martin FACCINELLI, Graz (AT)

(21) Appl. No.: 18/276,933

(22) PCT Filed: Dec. 21, 2021
(86) PCT No.: PCT/SG2021/050813

§ 371 Date: Aug. 11, 2023

(30) Foreign Application Priority Data
Feb. 12, 2021 (GB) 2102011.0

(51) Int. Cl. H01L 27/146; H01S 5/02234; H01S 5/02345; H01S 5/0236

(52) U.S. Cl. CPC H01L 27/14618; H01L 27/1469; H01S 5/02234; H01S 5/02345; H01S 5/0236; H01L 27/14634; H01S 5/183

(57) ABSTRACT

An optoelectronic module includes a driver die mounted on a substrate. The optoelectronic module also includes an optical sensor die mounted on an upper surface of the driver die. The optical sensor die includes at least one optical detector. The driver die is electrically connected to the optical sensor die. The optoelectronic module further includes an optical stack mounted via an adhesive layer to an upper surface of the optical sensor die above the at least one optical detector. The optoelectronic module additionally includes an encapsulant material that laterally encapsulates the optical stack.

### TECHNICAL FIELD

This disclosure relates to optoelectronic modules having an optical sensor die.

### BACKGROUND

Mobile communications devices, such as smart phones, tablets, laptop computers, and other portable computing devices, can include technologies to record three-dimensional images, sense motion and/or gestures. Digital recording methods use various types of miniature optoelectronic modules, which interact with cameras to record dynamical events in three-dimensional regions. These optoelectronic modules can be of various forms and deliver different types of functions. Some illuminate a wide area with very short pulses for Light Detection and Ranging (LIDAR) type measurements recording time of flight information. Others are pulsed or continuous wave (CVV), and project structured light patterns onto a scene. A digital camera records an image of the structured light pattern, and software algorithms are used to determine three-dimensional scene information from modifications in the patterned image.

The optoelectronic module may comprise an optical detector or sensor, such as a photodetector, photodiode, image sensor, e.g. a complementary metal-oxide-semiconductor (CMOS) sensor or charge coupled device CCD, photomultiplier, single photon avalanche diode or the like. The detector may comprise a plurality of radiation sensitive elements, such as for example a plurality of pixels.

The optoelectronic module may additionally include one or more devices for emission of visible and/or invisible radiation, such as a light-emitting diode, or a laser, such as a vertical cavity surface emitting laser (VCSEL) device. Various optical components (e.g., an optical diffuser and/or a microlens array) can be placed in the beam path to modify the beam properties for the specific application.

It is often desirable to have optical components (e.g. lenses, apertures etc.) to be well aligned to the optical detector. For example Time of Flight camera sensor packages need to have optical components well aligned to the optical detector (e.g. a sensor array) in order to enable a required spatial resolution (3D sensing). Current solutions for mobile applications are based on barrel optics—such as those applied to smartphone cameras. A threaded barrel encloses a plurality of lenses provided in a stacked arrangement above an optical sensor. The focal length is defined by the distance between the image sensor and the centre of the lens stack. The barrel is supported by a threaded housing. Such a known optoelectronic module has a plurality of components (e.g. the threaded barrel, threaded housing, the lenses, spacers provided between the lens) each associated with tolerances which contributes to a tolerance chain. To account for this tolerance chain, the threads on the housing and the barrel allow a screwing action to adjust the focal length (z-height) and this adjustment is performed by a manufacturer in a process known as active alignment during a testing phase of the optoelectronic module.

### SUMMARY

The application of standard camera optics and active alignment enables high spatial resolution to be achieved. However, the inventors have identified that the minimum dimensions achievable for such a known optoelectronic module are limited. For example, a known Time of Flight camera optoelectronic module has typical dimensions of >10 mm in at least one lateral dimension and >2 mm in height.

Furthermore, the robustness and reliability of the optoelectronic module is typically limited by the optical component. In particular, the maximum temperature of the thermoplastic materials (injection molded lenses) used in known optoelectronic modules are limited and standard reflow processes (SMT mounting) cannot be applied.

According to one aspect of the present disclosure there is provided an optoelectronic module comprising: a driver die mounted on a substrate; an optical sensor die mounted on an upper surface of the driver die, the optical sensor die comprising at least one optical detector, wherein the driver die is electrically connected to the optical sensor die; an optical stack mounted via an adhesive layer to an upper surface of the optical sensor die above the at least one optical detector; and an encapsulant material that laterally encapsulates the optical stack.

A multitude of optical stacks are preassembled at wafer level and prescreened based on performance such as accurate focal length. Such a prescreened optical stack is directly attached to the optical sensor die using the adhesive layer. By this approach no active alignment is needed because in contrast to known optoelectronic modules based on barrel optics, the only contributor to the tolerance chain is the adhesive layer and the tolerance associated with the adhesive layer is minimal. Thus the manufacturing process is simplified because no active alignment is needed.

The footprint of the optoelectronic module is substantially lower than known optoelectronic modules. This is achieved by a highly integrated package concept where the components are stacked on the driver die.

The robustness and reliability of known optoelectronic modules is typically limited by the optical components (e.g. lenses). In particular when using thermoplastic materials (injection molded lenses) the maximum temperature is limited and standard reflow processes (SMT mounting) cannot be applied. In embodiments, components of the optical stack are made from materials that are able to withstand high temperatures such that the optoelectronic module can assembled on a PCB with other components of a device by standard surface mount technology (SMT) processes. For example a reflow soldering process can be used to mount the optoelectronic module when reflow stable components for the optical stack are used.

The optoelectronic module of the present disclosure provides high reliability which is achieved by a number of contributing factors including the protective sealing of the encapsulant material, the minimal number of parts being used and the solderability of the optical stack.

Furthermore the encapsulant material advantageously minimizes the thermal-mechanical stress on the components and wire bonds.

The driver die may be electrically connected to the optical sensor die via one or more wire bonds, and the encapsulant material may encapsulates the one or more wire bonds.

The substrate may be a printed circuit board (PCB), a laminate substrate, a lead-frame substrate or the like. The driver die may be electrically connected to the substrate via one or more further wire bonds, wherein the encapsulant material encapsulates the one or more further wire bonds.

In some implementations, the encapsulant material covers an upper surface of a portion of the substrate.

In some implementations, the encapsulant material laterally encapsulates the driver die and covers a portion of the upper surface of the driver die.

In some implementations, the encapsulant material laterally encapsulates the optical sensor die and covers a portion of the upper surface of the optical sensor die.

The adhesive layer may be a die-attach film. Alternatively, the adhesive layer may be a glue.

Preferably, the encapsulant material is composed of an epoxy molding compound.

The optical stack may comprise at least one substrate with an optical element formed thereon. The at least one substrate may be made of glass. The lens may be made of a resin such as epoxy resin or other polymer material.

The optical stack may comprise a spacer enclosing a cavity of the optical stack. The spacer may be made of glass or a resin such as epoxy resin or other polymer material.

The optical stack may comprise a spacer enclosing a cavity of the optical stack, wherein the optical stack comprises a first substrate with a first optical element formed thereon, and a second substrate with a second optical element formed thereon, wherein the spacer is positioned between the first substrate and the second substrate.

The optical stack may comprise an optical filter.

An optical emitter may be mounted on the upper surface of the driver die, the optical emitter housed in a housing that is separated from the optical stack by the encapsulant material. The optical emitter may be a vertical cavity surface emitting laser (VCSEL). The encapsulant material blocks optical wavelengths emitted by the optical emitter and thus forms an optical barrier between the optical emitter and the at least one optical detector on the optical sensor die thereby minimizing optical cross-talk.

According to another aspect of the present disclosure there is provided a computing device comprising the optoelectronic module described herein.

According to another aspect of the present disclosure there is provided a method of manufacturing an optoelectronic module, the method comprising: mounting a driver die on a substrate; mounting an optical sensor die on an upper surface of the driver die, the optical sensor die comprising at least one optical detector; mounting an optical stack to an upper surface of the optical sensor die above the at least one optical detector using an adhesive layer; connecting the driver die to the optical sensor die; laterally encapsulating the optical stack, with an encapsulant material.

These and other aspects will be apparent from the embodiments described in the following. The scope of the present disclosure is not intended to be limited by this summary nor to implementations that necessarily solve any or all of the disadvantages noted.

### BRIEF DESCRIPTION OF THE PREFERRED EMBODIMENTS

Some embodiments of the disclosure will now be described by way of example only and with reference to the accompanying figures, in which:

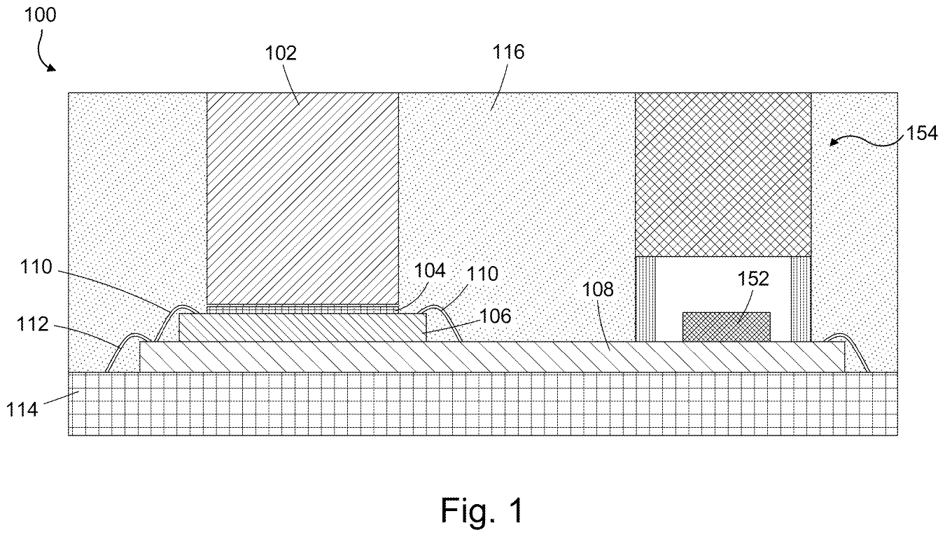

FIG. 1 illustrates an example optoelectronic module according to the present disclosure;

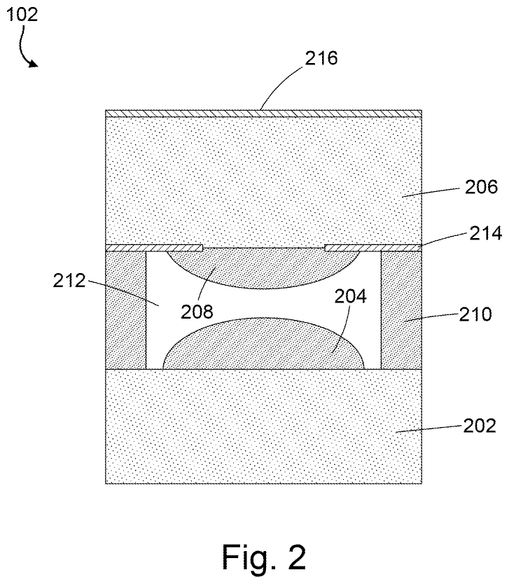

FIG. 2 illustrates an optical stack of the optoelectronic module;

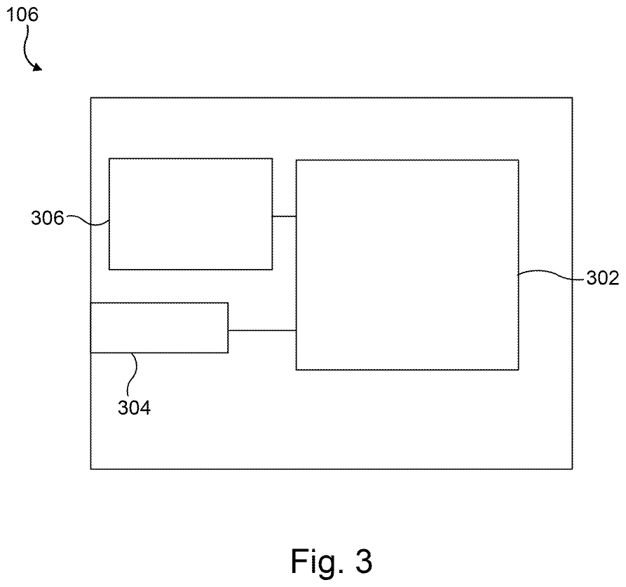

FIG. 3 illustrates a schematic block diagram of an optical sensor die;

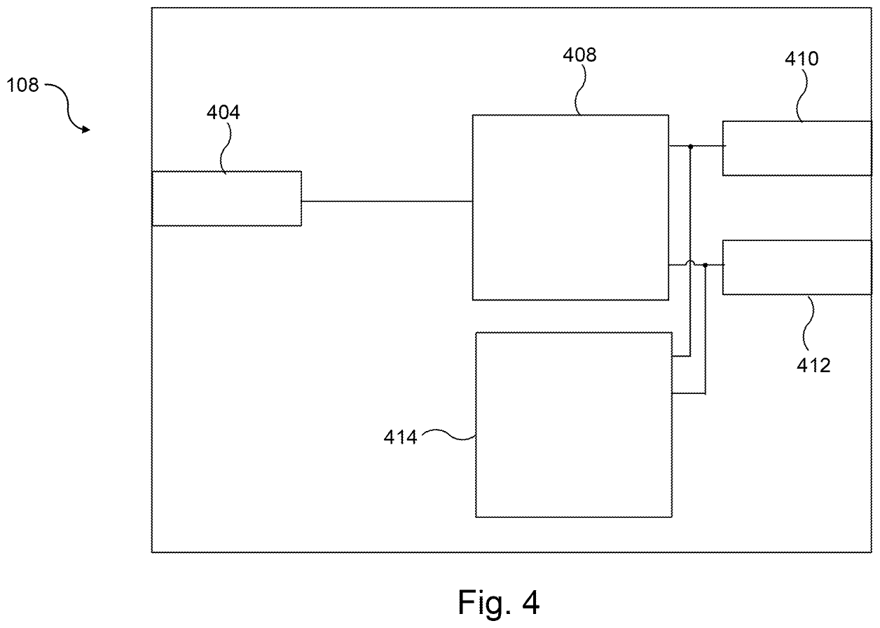

FIG. 4 illustrates a schematic block diagram of a driver die;

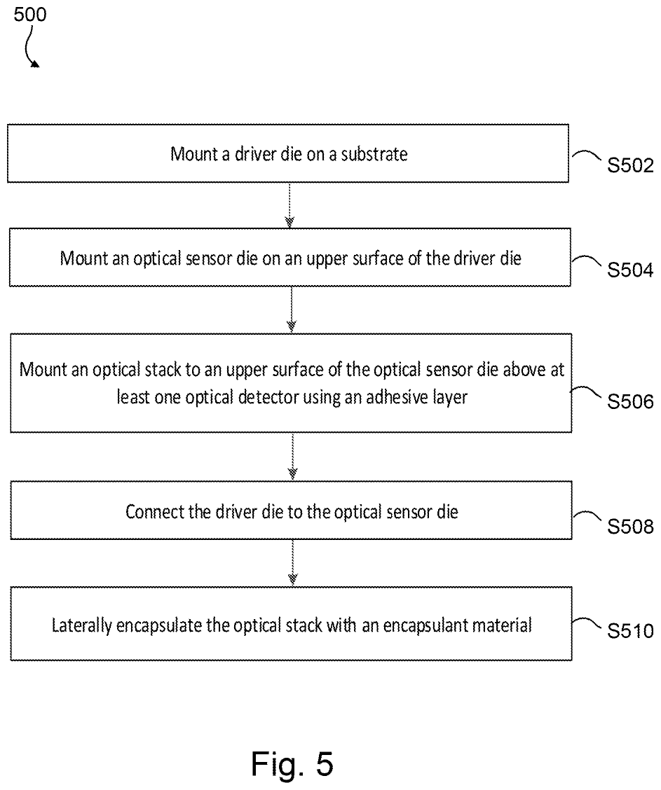

FIG. 5 illustrates a process for manufacturing an optoelectronic module according to the present disclosure; and

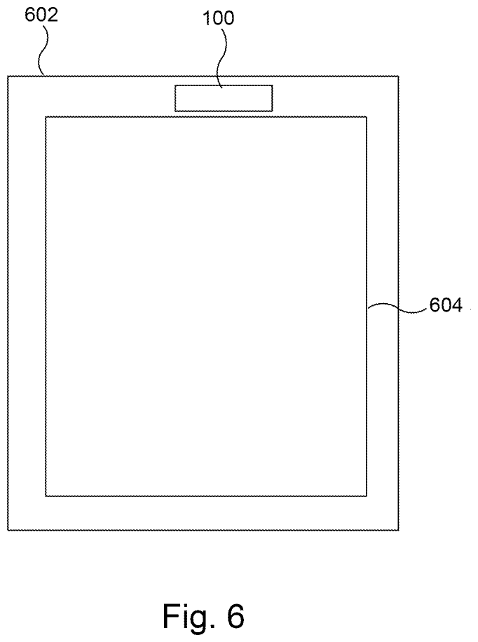

FIG. 6 illustrates a computing device comprising the optoelectronic module described herein.

### DETAILED DESCRIPTION OF THE PREFERRED EMBODIMENTS

Embodiments will now be described by way of example only with reference to the accompanying figures.

FIG. 1 illustrates an example optoelectronic module 100 in accordance with embodiments of the present disclosure.

As shown in FIG. 1, the optoelectronic module 100 comprises a substrate 114 on which a driver die (e.g., a semiconductor chip such as an application-specific integrated circuit) 108 is mounted.

The driver die 108 may be a high voltage ASIC providing a typical output voltage of 15V, comparatively higher than a typical supply voltage of 4V in consumer electronics. The substrate 114 may be a printed circuit board (PCB), a laminate substrate, a lead-frame substrate or the like. The backside of the substrate 114 can include SMT or other contacts for mounting the optoelectronic module 100, for example, to a printed circuit board.

Various different methods for mounting the driver die 108 to the substrate 114 may be used. The driver die 108 may be mounted to the substrate 114 by gluing (e.g. using a die attach film or a liquid adhesive) or soldering.

Electrical connections such as wire bonds 112 and/or contact pads on the backside of the driver die 108 can be provided to couple the driver die 108 to contact pads on the substrate 114.

An optical sensor die 106 (e.g., a semiconductor chip such as an application-specific integrated circuit) is mounted to an upper surface of the driver die 108. Various different methods for mounting the optical sensor die 106 to the driver die 108 may be used. The optical sensor die 106 may be mounted to the driver die 108 by gluing (e.g. using a die attach film or a liquid adhesive) or soldering. The optical sensor die 106 may be a time-of-flight optical sensor die, however embodiments of the present disclosure are not limited to this example.

Electrical connections such as wire bonds 110 and/or contact pads on the backside of the optical sensor die 106 can be provided to couple the optical sensor die 106 to contact pads on the driver die 108.

The optical sensor die 106 comprises one or more optical detectors. The optical detectors are photosensitive elements each of which is operable to produce a signal in response to a received dose of radiation (for example visible or infrared light). That is, the optical detectors convert received radiation (for example visible or infrared) into electrical signals. The optical detectors may be based on an active-pixel sensor technology and may comprise, for example, an array of complimentary metal-oxide semiconductor (CMOS) pixels.

The optical detectors are arranged such that light incident on an upper surface of the optical sensor die 106 is incident on the optical detectors.

A preassembled optical stack 102 is mounted to an upper surface of the optical sensor die 106 above the optical detectors. The optical stack 102 comprises a plurality of optical components stacked vertically on top of each other.

The optical stack 102 is preassembled at wafer level and prescreened based on performance such as accurate focal length. The optical stack is mounted to an upper surface of the optical sensor die 106 using an adhesive layer 104. The adhesive layer 104 may be a die attach film or a liquid adhesive.

The optical stack 102 is arranged to project at least a portion of received radiation onto the optical detectors of the optical sensor die 106. The optical stack 102 is discussed in more detail with reference to FIG. 2.

As shown in FIG. 1, an encapsulant material 116 laterally encapsulates the optical stack 102. That is, the encapsulant material 116 covers the outer sidewalls of the optical stack 102.

In the example shown in FIG. 1, the encapsulant material 116 may encapsulate the wire bonds 110 which couples the optical sensor die 106 to contact pads on the driver die 108, and also encapsulate the wire bonds 112 which couples the driver die 108 to contact pads on the substrate 114. The encapsulant material 116 may cover portions of the upper surface of the optical sensor die 106 which are not in contact with the optical stack 102. The encapsulant material 116 may laterally encapsulate the optical sensor die 106 (e.g. cover sidewalls of the optical sensor die 106). The encapsulant material 116 may covers portions of the upper surface of the driver die 108 which are not in contact with the optical sensor die 106. The encapsulant material 116 may laterally encapsulate the driver die 108 (e.g. cover sidewalls of the driver die 108). The encapsulant material 116 may cover portions of the substrate 114 which are not in contact with the driver die 108.

The encapsulant material 116 may be an epoxy molding compound, for example an epoxy resin such as a black epoxy resin, or other polymer material.

The encapsulant material 116 may be applied by a film assisted transfer molding (FAM) process after which the encapsulant material 116 is cured.

As shown in FIG. 1, the optoelectronic module 100 optionally further comprises an optical emitter 152 housed in a housing 154 that is separated from the optical stack by the encapsulant material 116. The housing 154 comprises a wall or walls laterally surrounding the optical emitter 152. Embodiments of the present disclosure are not limited to the optoelectronic module 100 comprising the optical emitter 152 and the housing 154, such components may be provided in a separate module or package.

The optical emitter 152 may comprise one or more light emitting diodes (LEDs), lasers, or other devices. In some embodiments, the optical emitter 152 comprises one or more vertical-cavity surface-emitting lasers (VCSELs). The optical emitter 152 may be configured to emit visible light and/or invisible radiation, such as infrared or near-infrared radiation.

The optical emitter 152 is mounted to the upper surface of the driver die 108. Various different methods for mounting the optical emitter 152 to the driver die 108 may be used. The optical emitter 152 may be mounted to the driver die 108 by gluing with a conductive adhesive or soldering. The optical emitter 152 is electrically connected to the driver die 108 (e.g. using wirebonds).

The housing 154 comprises an interlock feature. The interlock feature may be disposed on a surface of a transparent substrate forming part of the housing 154. In an alternative example, the interlock feature may be at least partially encapsulated inside the transparent substrate. The interlock feature may comprise, for example, indium tin oxide, chromium oxide, or any other suitable electrically conductive material. The interlock feature is electrical connected to the driver die 108.

In these embodiments, the encapsulant material 116 is intransparent to the relevant optical wavelengths emitted by the optical emitter 152 and forms an optical barrier between the optical emitter 152 and the optical detectors of the optical sensor die 106 thereby minimizing optical cross-talk i.e. direct transmission of light from the optical emitter 152 to the optical sensor die 106.

FIG. 2 illustrates an optical stack 102. It will be appreciated that the optical stack 102 shown in FIG. 2 is merely an example and embodiments of the present disclosure are not limited to using the optical stack 102 shown in FIG. 2.

The optical stack 102 may comprise at least one transparent substrate with an optical element formed thereon. The transparent substrate is transmissive of light having a wavelength or wavelengths of interest. For example, in embodiments whereby the optoelectronic module 100 comprises an optical emitter 152, the transparent substrate is transmissive of wavelengths of light emitted by the optical emitter 152.

The transparent substrate preferably comprises glass. However, other materials are suitable, for example plastic. In some embodiments, the substrate can comprise SiO₂ or “display” glass, such as Schott D263T-ECO or Borofloat 33, Dow-Corning Eagle 2000.

The optical element may comprise, for example, one or more lenses, a microlens array, and/or a diffuser. The optical element may be made of an epoxy molding compound, for example an epoxy resin.

FIG. 2 shows an optical stack 102 comprising a first transparent substrate 202 supporting a first optical element 204 on the upper surface of the first transparent substrate 202, and a second transparent substrate 206 supporting a second optical element 208 on the lower surface of the second transparent substrate 206 such that the optical elements 204,204 are facing each other.

The first transparent substrate 202 and the second transparent substrate 206 may be made of the same material or different materials. The first optical element 204 may be identical to, or different to, the second optical element 208.

The first transparent substrate 202 is separated from the second transparent substrate 206 by way of a spacer 210. The spacer 210 may be made of glass. The spacer 210 may be made of an epoxy molding compound, for example an epoxy resin. The spacer 210 forms a cavity 212 filled with air.

Whilst FIG. 2 illustrates the optical stack 102 as having two transparent substrates and two optical elements, this is merely an example and more than two transparent substrates and more than two optical elements may be used within the optical stack 102. Whilst FIG. 2 illustrates the optical elements facing in different directions, optical elements used within the optical stack 102 may face in the same direction. Whilst FIG. 2 illustrates the optical elements being formed of concave lenses, this is merely an example and convex lenses may be used within the optical stack 102.

The optical stack 102 may comprise one or more optical filters. The one or more optical filters may comprise a band-pass filter; it will appreciated that other filter operations can be performed by the one or more optical filters. A transparent substrate of the optical stack 102 can serve as a carrier for the one or more optical filter. FIG. 2 illustrates an optical filter 216 on an upper surface of the second transparent substrate 206. It will be appreciated that the location of the optical filter 216 shown in FIG. 2 is merely an example and the optical filter 216 may be positioned within the optical stack 102 at alternative locations.

The optical stack 102 may comprise an aperture 214. A transparent substrate of the optical stack 102 can serve as a carrier for the aperture 214. It will be appreciated the location of the aperture 214 shown in FIG. 2 is merely an example and the aperture 214 may be positioned within the optical stack 102 at alternative locations.

In some embodiments, each of the components of the optical stack 102 are made from a reflow-stable material i.e., a thermally stable material whose transmissivity remains substantially constant even when subjected to relatively high operating temperatures (e.g., temperatures above 260° C. for stability of the shape of a lens).

FIG. 3 illustrates a simplified schematic block diagram of the optical sensor die 106.

As shown in the FIG. 3, the optical sensor die 106 comprises signal processing circuitry 302, coupled to an interface 304 and one or more optical detectors 306 (e.g. photodiodes). In some embodiments, the primary function of the signal processing circuitry 302 is to convert the signal from the optical detectors into a 3-dimensional image. The particular implementation of the signal processing circuitry 302 is outside the scope of the present disclosure, but the signal processing circuitry 302 would typically include time-to-digital converters, memory, central processing units and quenching circuitry for the optical detectors.

As noted above, the optical detectors 306 are photosensitive elements each of which is operable to produce a signal in response to a received dose of radiation (for example visible or infrared light). In embodiments in which the optoelectronic module 100 comprises the optical emitter 152, the optical detectors 306 may be configured to detect light having wavelengths corresponding to those emitted by the optical emitter 152.

The interface 304 enables the optical sensor die 106 to electrically connect to the driver die 108. The interface 304 may comprise one or more contact pads for connecting to contact pads on the driver die 108 (e.g. via wire bonds 110).

FIG. 4 illustrates a simplified schematic block diagram of the driver die 108.

The driver die 108 comprises an interface 404 which enables the driver die 108 to electrically connect to the optical sensor die 106. The interface 404 may comprise one or more contact pads for connecting to contact pads on the optical sensor die 106 (e.g. via wire bonds 110).

The driver die 108 additionally comprises optical emitter driver circuitry 408 and fault detection circuitry 414.

The optical emitter driver circuitry 408 is shown as being coupled to an interface 410 and an interface 412. It will be appreciated from the below that one or both of these interfaces may be provided.

In embodiments where the optoelectronic module 100 comprises an optical emitter 152 mounted to the driver die 108, the interface 410 enables the optical emitter driver circuitry 408 to electrically connect to the optical emitter 152. The interface 410 may comprise one or more contact pads for connecting to contact pads on the optical emitter 152 (e.g. via wire bonds).

The interface 412 enables the optical emitter driver circuitry 408 to electrically connect to the substrate 114. The interface 412 may comprise one or more contact pads for connecting to contact pads on the substrate 114 (e.g. via wire bonds). In embodiments where the optical emitter 152 is external to the optoelectronic module 100, the interface 412 enables the optical emitter driver circuitry 408 to communicate with the external optical emitter 152.

The optical emitter driver circuitry 408 drives the optical emitter 152 with one or more electrical signals such as one or more electrical currents causing the optical emitter 152 to emit light through the housing 154. The optical sensor die 106 may communicate with the optical emitter driver circuitry 408 of the driver die 108 to trigger the emission of light from the optical emitter 152. For example, in embodiments whereby the optoelectronic module is a time-of-flight module the optical sensor die 106 triggers the optical emitter driver circuitry 408 to control the optical emitter 152 to send out a VCSEL pulse. That is, the optical emitter driver circuitry 408 generates ultra-short voltage pulses for the optical emitter 152 (e.g. a VCSEL) using a charge pump.

The fault detection circuitry 414 is coupled to the interlock feature of the housing 154. The fault detection circuitry 414 is also coupled to the interface 410 and/or the interface 412. In embodiments where the optoelectronic module 100 comprises an optical emitter 152 mounted to the driver die 108, the interface 410 enables the fault detection circuitry 414 to electrically connect to the optical emitter 152. The interface 412 enables the fault detection circuitry 414 to electrically connect to the substrate 114 for transmission of an alert to a remote device, or in embodiments where the optical emitter 152 is external to the optoelectronic module 100, to enable the fault detection circuitry 414 to communicate with the external optical emitter 152.

Electrical current is supplied to the interlock feature of the housing 154. The optical emitter driver circuitry 408 and/or the fault detection circuitry 414 may supply electrical current to the interlock feature.

The fault detection circuitry 414 monitors an electrical parameter associated with the interlock feature. For example, the fault detection circuitry 414 may be configured to monitor a resistance and/or capacitance of the interlock feature. The fault detection circuitry 414 may be configured, for example, to determine whether the electrical parameter has fallen outside of a pre-determined range, which may indicate that the interlock feature has become damaged and/or disconnected from the housing 154, and therefore that the integrity of one or more components of the optoelectronic module 100 has become compromised. Alternatively, or in addition, the fault detection circuitry 414 may be configured to detect an interruption in electrical conduction through the interlock feature. The fault detection circuitry 414 may be further configured to transmit an alert to a user via interface 412 to inform the user that the optoelectronic module 100 may be unsafe. Alternatively, or in addition, the fault detection circuitry 414 may be coupled to the optical emitter 152 via interface 410 or interface 412 (if the optical emitter 152 is external to the optoelectronic module 100), and the fault detection circuitry 414 may be configured to transmit a control signal to the optical emitter 152. The control signal may, for example, direct the optical emitter 152 to turn off or otherwise regulate (e.g. reduce) its optical power output to a safe level. The interlock feature therefore serves to prevent accidental harm to a person that may otherwise be caused by direct exposure to high power radiation emission.

FIG. 5 illustrates a process 500 for manufacturing an optoelectronic module 100 according to the present disclosure.

At step S502 the driver die 108 is mounted to the substrate 114. As noted above, various different methods may be used for mounting the driver die 108 to the substrate 114.

If contact pads are provided on the backside of the driver die 108 in positions corresponding to contact pads on the upper surface of the substrate 1114, the mounting of the driver die 108 to the upper surface of the substrate 114 may electrically connect the driver die 108 to the substrate 114. Alternatively, the driver die 108 may be electrically connected to the substrate 114 using one or more wire bonds 112.

At step S504, the optical sensor die 106 is mounted to the upper surface of the driver die 108. As noted above, various different methods may be used for mounting the optical sensor die 106 to the driver die 108.

At step S506, a preassembled optical stack 102 is mounted to the upper surface of the optical sensor die 106 using an adhesive layer 104. The preassembled optical stack 102 is positioned above the optical detectors 306 such that light incident on the optoelectronic module 100 will pass through the optical stack 102 before being incident on the optical detectors 306.

At step S508 the driver die 108 is electrically connected to the optical sensor die 106.

If contact pads are provided on the backside of the optical sensor die 106 in positions corresponding to contact pads on the upper surface of the driver die 108, the mounting of the optical sensor die 106 to the upper surface of the driver die 108 performed at step S504 may electrically connect the driver die 108 to the optical sensor die 106. Alternatively, step S508 may comprise electrically connecting the driver die 108 to the optical sensor die 106 using one or more wire bonds 110.

At step S510 the optical stack 102 is laterally encapsulated with the encapsulant material 116 (e.g. the encapsulant material 116 covers sidewalls of the optical stack 102).

As noted above, the encapsulant material 116 may laterally encapsulate the optical sensor die 106 (e.g. cover sidewalls of the optical sensor die 106) and/or the driver die 108 (e.g. cover sidewalls of the driver die 108). In embodiments where the wire bonds 110 are used, the encapsulant material 116 encapsulates the wire bonds 110. Similarly, in embodiments where the wire bonds 112 are used, the encapsulant material 116 encapsulates the wire bonds 112.

The encapsulant material 116 may be applied by a film assisted transfer molding (FAM) process after which the encapsulant material 116 is cured.

Whilst steps of the process 500 are described in a particular order, embodiments of the present disclosure are not limited to the steps of the process 500 being performed in the order described and the steps of the process 500 may be performed in an alternative order.

FIG. 6 illustrates a computing device 602 comprising the optoelectronic module 100 according to any of the embodiments described herein. The computing device 602 shown in FIG. 6 is a mobile phone with a display 604, however it will be appreciated that an apparatus according to embodiments of the present disclosure may be incorporated into other types of computing device (whether mobile or not) e.g. a tablet device, a laptop computer, a gaming device. For example, the computing device 602 may be a wearable device (e.g. a smartwatch).

The optoelectronic module 100 can be utilised in a number of different applications including laser detection auto focus (LDAF), 3D imaging and presence detection.

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in any embodiments, whether alone or in any appropriate combination with any other feature disclosed or illustrated herein.

### LIST OF REFERENCE NUMERALS

100 optoelectronic module
102 optical stack
104 adhesive layer
106 optical sensor die
108 driver die
110 wire bonds
112 wire bonds
114 substrate
116 encapsulant material
152 optical emitter
154 housing
202 transparent substrate
204 optical element
206 transparent substrate
208 optical element
210 spacer
212 cavity
214 aperture
216 optical filter
302 signal processing circuitry
304 interface
306 optical detectors
404 interface
408 optical emitter driver circuitry
410 interface
412 interface
414 fault detection circuitry
500 process
S502-S510 process steps
602 computing device
604 display

1. An optoelectronic module comprising:
a driver die mounted on a substrate;
an optical sensor die mounted on an upper surface of the driver die, the optical sensor die comprising at least one optical detector, wherein the driver die is electrically connected to the optical sensor die;
an optical stack mounted via an adhesive layer to an upper surface of the optical sensor die above the at least one optical detector; and
an encapsulant material that laterally encapsulates the optical stack.

2. The optoelectronic module of claim 1, wherein the driver die is electrically connected to the optical sensor die via one or more wire bonds, and the encapsulant material encapsulates the one or more wire bonds.

3. The optoelectronic module of claim 1, wherein the driver die is electrically connected to the substrate via one or more further wire bonds, wherein the encapsulant material encapsulates the one or more further wire bonds.

4. The optoelectronic module of claim 1, wherein the encapsulant material covers an upper surface of a portion of the substrate.

5. The optoelectronic module of claim 1, wherein the encapsulant material laterally encapsulates the driver die and covers a portion of the upper surface of the driver die.

6. The optoelectronic module of claim 1, wherein the encapsulant material laterally encapsulates the optical sensor die and covers a portion of the upper surface of the optical sensor die.

7. The optoelectronic module of claim 1, wherein the adhesive layer is a die-attach film.

8. The optoelectronic module of claim 1, wherein the adhesive layer is a glue.

9. The optoelectronic module of claim 1, wherein the encapsulant material is composed of an epoxy molding compound.

10. The optoelectronic module of claim 1, wherein the optical stack comprises at least one substrate with an optical element formed thereon.

11. The optoelectronic module of claim 1, wherein the optical stack comprises a spacer enclosing a cavity of the optical stack, wherein the optical stack comprises a first substrate with a first optical element formed thereon, and a second substrate with a second optical element formed thereon, wherein the spacer is positioned between the first substrate and the second substrate.

12. The optoelectronic module of claim 1, wherein the optical stack comprises an optical filter.

13. The optoelectronic module of claim 1, wherein an optical emitter is mounted on the upper surface of the driver die, the optical emitter housed in a housing that is separated from the optical stack by the encapsulant material.

14. The optoelectronic module of claim 13, wherein optical emitter comprises a vertical cavity surface emitting laser.

15. A computing device comprising the optoelectronic module of claim 1.

16. A method of manufacturing an optoelectronic module, the method comprising:
mounting a driver die on a substrate;
mounting an optical sensor die on an upper surface of the driver die, the optical sensor die comprising at least one optical detector;
mounting an optical stack an upper surface of the optical sensor die above the at least one optical detector using an adhesive layer;
connecting the driver die to the optical sensor die; and
laterally encapsulating the optical stack with an encapsulant material.
